(19) United States
(12) Patent Application Publication
(10) Pub. No.: US 2013/0047920 A1
(43) Pub. Date: Feb. 28, 2013

(54) DEPOSITION DEVICE FOR FORMING ORGANIC LAYER USING JOULE-HEATING AND DEVICE FOR FABRICATING ELECTROLUMINESCENT DISPLAY DEVICE USING THE DEPOSITION DEVICE

(71) Applicants: Jae-Sang RO, Seoul (KR); Won-Eui Hong, Seoul (KR)

(72) Inventors: Jae-Sang RO, Seoul (KR); Won-Eui Hong, Seoul (KR)

(73) Assignee: EnSilTech Corporation, Seoul (KR)

(21) Appl. No.: 13/591,556

(22) Filed: Aug. 22, 2012

(30) Foreign Application Priority Data
Aug. 26, 2011 (KR) 10-2011-85856

(51) Int. Cl. H05B 33/10; B05B 1/18

(52) U.S. Cl. 118/641

(57) ABSTRACT

There are provided a deposition device for forming an organic layer using Joule heating and a device for fabricating an electroluminescent display device using the deposition device that includes a cleansing device, an organic matter coating device, an electric field applying device and a loadlock chamber. The cleansing device cleanses a donor substrate. The organic matter coating device coats an organic matter on the donor substrate. The electric field applying device allows the organic matter to be transferred onto an element substrate. Here, the organic matter is heated by the Joule-heating generated by applying an electric field to the donor substrate having the organic matter formed thereon. The loadlock chamber loads or carries out the donor substrate into/from the electric field applying device. Accordingly, the present invention is advantageous in fabricating a large-scale element, and it is possible to increase a processing speed and to reduce device cost.

### BACKGROUND OF THE INVENTION

1. Field of the Invention

The present invention relates to a deposition device for forming an organic layer using Joule-heating and a device for fabricating an electroluminescent display device using the deposition device. More particularly, the present invention relates to a deposition device for forming an organic layer using Joule-heating and a device for fabricating an electroluminescent display device using the deposition device, in which the organic layer is evaporated by providing heat to the organic layer using the Joule-heating, so that the evaporated organic layer is transferred and deposited on an element substrate.

2. Description of the Related Art

Among flat panel display devices, an electroluminescent display device has a high response speed of 1 ms or less, low power consumption and no problem of viewing angle because of self-luminescence. Thus, the electroluminescent display device is advantageous as a moving picture display medium, regardless of the size of the device. Further, it is possible to fabricate the device at a low temperature, and the fabrication process of the device is simple based on the existing semiconductor processing technology. Therefore, the electroluminescent display device has come into the spotlight as a next-generation flat panel display device in the future.

The thin film formed in the flat panel display device or electroluminescent display device may be divided into a high molecular element and a low molecular element according to the material and process used in the formation of the thin film.

For example, in the case of an inkjet printing method in the formation method of a high molecular or low molecular light emitting layer, the material of organic layers except the light emitting layer is limited, and there is an inconvenience that a structure for inkjet to printing should be formed on a substrate.

In a case where the light emitting layer is formed through a deposition process, a separate metal mask is used. As the flat panel display device is large scaled, the metal mask should also be large scaled. In this case, the drooping of the mask may occur as the flat panel display device is large scaled, and therefore, it is difficult to fabricate a large-scale element.

FIG. 1 is a cross-sectional view schematically illustrating a related art deposition device having a mask for deposition.

Referring to FIG. 1, to deposit a thin film of an electroluminescent display device, e.g., an organic layer including a light emitting layer using a mask 1, a frame 4 coupled to the mask 1 is mounted at the side corresponding to a thin-film deposition crucible 3 installed in a vacuum chamber 2, and an object 5 to be formed with a thin film, etc. is mounted above the frame 4. The mask 1 is closely adhered to the object 5 to be formed with the thin film, etc. by driving a magnet unit 6 for closely adhering the mask 1 supported by the frame 4 to the object 5 to be formed with the thin film, etc. above the object 5. In this state, a material contained in the thin-film deposition crucible 3 is deposited on the object 5 through the operation of the thin-film deposition crucible 3.

However, as described above, in the formation of the thin film using the deposition device having the mask for deposition, the mask for deposition should be large scaled as the flat panel display device is large scaled. In this case, it is difficult to perform the alignment between the mask and the object due to the drooping of the mask, etc., and therefore, it is difficult to fabricate a large-scale element.

Meanwhile, there has been disclosed a technique for forming an organic light emitting layer using a Joule-heating device. In the technique, an organic light emitting layer is first formed on a donor substrate, and the donor substrate and an element substrate are then placed opposite to each other. Subsequently, the donor substrate is heated using Joule-heating, and the organic light emitting layer formed on the donor substrate is deposited on the element substrate.

In the technique, as shown in FIG. 2, when the electroluminescent display device is fabricated, the element substrate passes through deposition chambers 10 to 40 so as to form the other organic or inorganic layers except the organic light emitting layer. On the other hand, the donor substrate for forming the organic light emitting layer passes through a deposition chamber 50 so as to form the organic light emitting layer on the donor substrate.

In this case, both the element substrate and the donor substrate passing through the deposition chamber 50 are placed in the same direction, and hence any one of the two substrates should be reversed so that the two substrates are disposed opposite to each other.

To allow the donor substrate of the two substrates to face upward, the position of the donor substrate is reversed by passing through a reverse chamber 60.

Then, the organic light emitting layer is formed on the element substrate by loading the element substrate and the donor substrate into an electric field applying chamber 70 and then applying an electric field to the donor substrate.

However, since the deposition chamber 50 for depositing the organic light emitting layer and the reverse chamber 60 should be separately provided in this case, equipments are added, and the TAC time is also increased as a process is added.

### SUMMARY OF THE INVENTION

The present invention is conceived to solve the aforementioned problems. Accordingly, an object of the present invention is to provide a deposition device for forming an organic layer and a device for fabricating an electroluminescent display device, which can easily fabricate a large-scale element, perform fabrication at low cost using simple processing equipments, and reduce a processing time.

According to an aspect of the present invention, there is provided a deposition device for forming an organic layer using Joule heating, including: a cleansing device configured to cleanse a donor substrate; an organic matter coating device configured to coat an organic matter on the donor substrate; an electric field applying device configured to allow the organic matter to be transferred onto an element substrate, wherein the organic matter is heated by the Joule-heating generated by applying an electric field to the donor substrate having the organic matter formed thereon; and a loadlock chamber configured to load or carry out the donor substrate into/from the electric field applying device.

According to another aspect of the present invention, there is provided a device for fabricating an electroluminescent display device, including: a conveying chamber configured to have a conveying mechanism for conveying a substrate; at least one deposition chamber configured to be placed at an outside of the conveying chamber; at least one deposition device for forming an organic layer using Joule-heating; and a loadlock chamber configured to load the substrate into the conveying chamber or carry out the substrate from the conveying chamber, wherein the deposition device includes a cleansing device configured to cleanse a donor substrate; an organic matter coating device configured to coat an organic matter on the donor substrate; an electric field applying device configured to allow the organic matter to be transferred onto an element substrate, wherein the organic matter is heated by the Joule-heating generated by applying an electric field to the donor substrate having the organic matter formed thereon; and a loadlock chamber configured to load or carry out the donor substrate into/from the electric field applying device.

According to still another aspect of the present invention, there is provided a device for fabricating an electroluminescent display device, including: a loadlock chamber configured to load an element substrate; a deposition device for forming an organic layer using Joule-heating, configured to have one end connected to the loadlock chamber; a loadlock chamber for carrying out the element substrate, configured to carry out the element substrate, and be connected to the other end of the deposition device; and at least one deposition chamber configured to be connected to the loadlock chamber, wherein the deposition device includes a cleansing device configured to cleanse a donor substrate; an organic matter coating device configured to coat an organic matter on the donor substrate; an electric field applying device configured to allow the organic matter to be transferred onto an element substrate, wherein the organic matter is heated by the Joule-heating generated by applying an electric field to the donor substrate having the organic matter formed thereon; and a loadlock chamber configured to load or carry out the donor substrate into/from the electric field applying device.

The cleansing device may include a solvent supply tub configured to supply a solvent; a shower head configured to spray the solvent supplied from the solvent supply tub onto the donor substrate; a tub configured to accommodate the solvent sprayed from the shower head and the organic matter dissolved in the solvent; a blower configured to blow and remove remaining solvent not removed in the tub and the organic matter dissolved in the remaining solvent; and a solvent collection tub configured to collect the solvent and the organic matter, accommodated in the tub.

The deposition device may further include an organic matter separation tub configured to be connected to the solvent collection tub, the organic matter separation tub may separate the solvent and the organic matter, collected in the solvent collection tub, and the separated organic matter may be again supplied to the organic matter coating device.

The organic matter coating device may include a shower head configured to spray an organic matter; a stage configured to mount the donor substrate; and an organic matter supply tub configured to be connected to the shower head so as to supply the organic matter.

The deposition device may further include a drying device.

The electric field applying device may include a power supply device; an electric field applying electrode configured to be electrically connected to the power supply device; a stage configured to mount a substrate; and a chuck configured to be placed opposite to the stage.

The at least one deposition device may be a deposition device for forming at least one of a hole injection layer, a hole transport layer, a hole blocking layer, a light emitting layer, an electron blocking layer, an electron transport layer and an electron injection layer.

Accordingly, the present invention is advantageous in fabricating a large-scale element, and the TAC time is decreased, thereby increasing a processing speed.

Further, since an organic layer is formed on a donor substrate through a wet process, the loss of an organic material is decreased as compared with that in the process through deposition.

Further, since a deposition chamber and a reversing chamber are not required when the organic layer formed on the donor substrate, the price of the device can be decreased.

Further, since the device of the present invention is easily configured using an in-line apparatus, it is possible to reduce processing time and to save processing cost and device fabrication cost.

### BRIEF DESCRIPTION OF THE DRAWINGS

Preferred embodiments of the present invention can be understood in more detail from the following description taken in conjunction with the accompanying drawings, in which:

FIG. 1 is a cross-sectional view schematically illustrating a related art deposition device having a mask for deposition;

FIG. 2 is a plan view schematically illustrating a related art device for fabricating an electroluminescent display device using Joule-heating;

FIG. 3 is a schematic view illustrating a configuration of a deposition device for forming an organic layer using Joule-heating according to an embodiment of the present invention;

FIG. 4 is a view illustrating a cleansing device in configuration of the deposition device according to the embodiment of the present invention;

FIG. 5 is a view illustrating an organic matter coating device in the configuration of the deposition device according to the embodiment of the present invention;

FIGS. 6A to 6C are views illustrating embodiments of an electric field applying device in the configuration of the deposition device according to the present invention;

FIG. 7 is a plan view illustrating a device for fabricating an electroluminescent display device to which the deposition device of FIGS. 3 to 6C according to a first embodiment of the present invention; and

FIG. 8 is a plan view illustrating a device for fabricating an electroluminescent display device to which the deposition device of FIGS. 3 to 6C according to a second embodiment of the present invention.

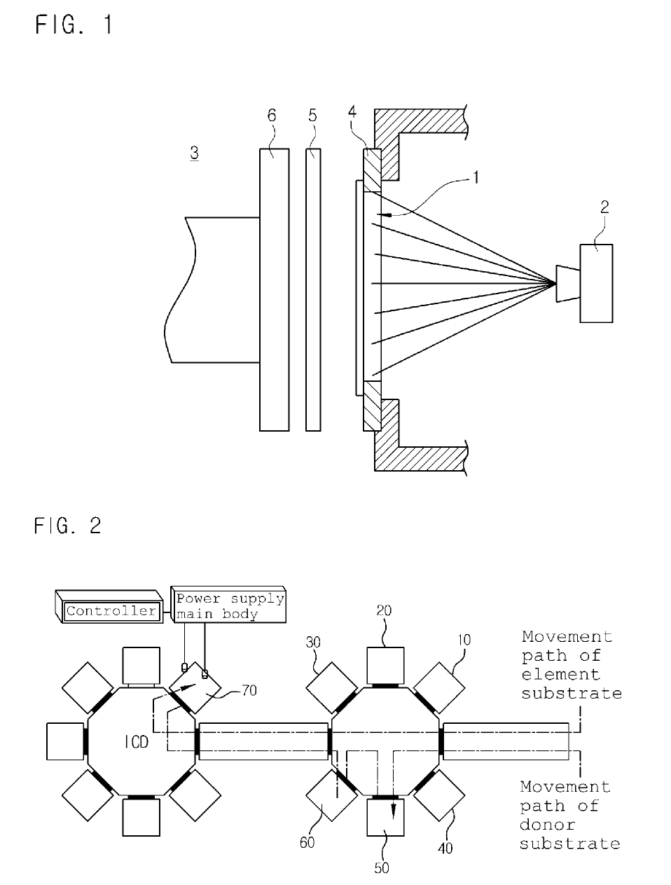

### DETAILED DESCRIPTION OF THE INVENTION

Hereinafter, preferred embodiments of the present invention will be described in detail with reference to the accompanying drawings. The following embodiments are provided only for illustrative purposes so that those skilled in the art can fully understand the spirit of the present invention. Therefore, the present invention is not limited to the following embodiments but may be implemented in other forms. In the drawings, the widths, lengths, thicknesses and the like of elements are exaggerated for convenience of illustration. Like reference numerals indicate like elements throughout the specification and drawings.

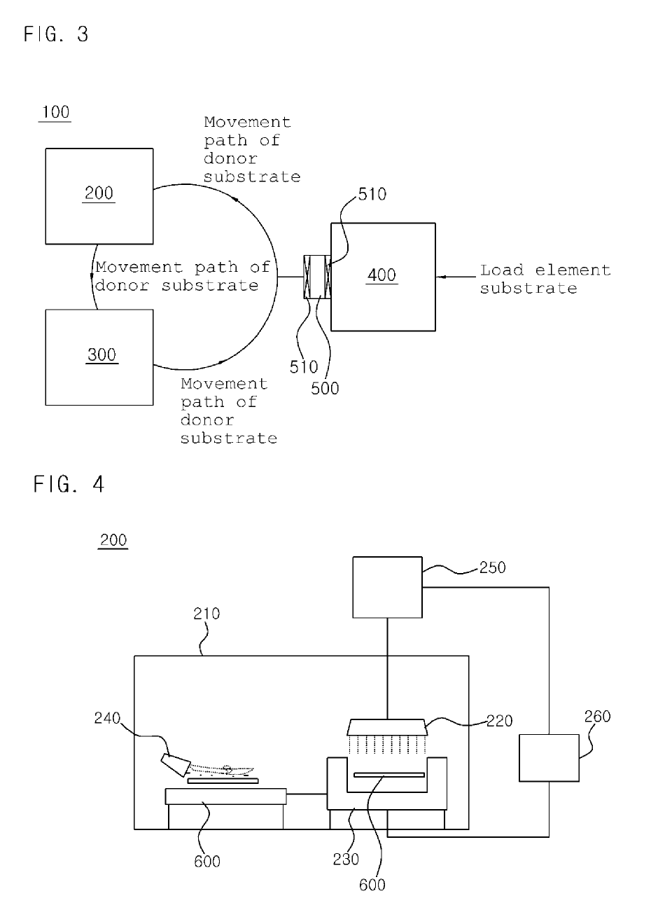

FIG. 3 is a schematic view illustrating a configuration of a deposition device for forming an organic layer using Joule-heating according to an embodiment of the present invention.

Referring to FIG. 3, the deposition device 100 according to the embodiment of the present invention includes a cleansing device 200 for cleansing a donor substrate, an organic matter coating device 200 for coating an organic matter on the donor substrate, a loadlock chamber 500 for loading the donor substrate having the organic matter coated thereon into an electric field applying device 400, and the electric field applying device 400 that allows the organic matter to be transferred onto an element substrate. Here, the organic matter is heated by the Joule-heating generated by applying an electric field to the donor substrate having the organic matter formed thereon.

In the deposition device according to the embodiment of the present invention, the donor substrate is transported by a transportation means such as a conveyer provided between the devices.

Detailed configurations and operations of the devices will be described below.

First, a donor substrate 600 on which an organic matter is formed as a layer is loaded into the cleansing device 200.

FIG. 4 is a view illustrating the cleansing device in configuration of the deposition device according to the embodiment of the present invention.

Referring to FIG. 4, the cleansing device 200 includes a cleansing chamber 210 maintained under a nitrogen atmosphere, a shower head 220 for cleansing the donor substrate 600, a tub 230 for accommodating a solvent for cleansing, sprayed from the shower head 220, and a blower 240 for removing residues remaining on the donor substrate 600. The cleansing device 200 further includes a solvent supply tub 250 for supplying the solvent for cleansing to the shower head 220, and a solvent collection tub 260 for collecting the solvent accommodated in the tub 230.

A conductive layer is formed on the donor substrate 600 so as to generate the Joule-heating in a subsequent electric field applying process. The conductive layer may be made of a metal or metal alloy. The metal or metal alloy may be, for example, molybdenum (Mo), titanium (Ti), chromium (Cr), moly-tungsten (MoW), etc. However, the present invention is not limited thereto.

Meanwhile, the conductive layer is formed to have a shape identical to that of an organic layer pattern to be stacked on the element substrate.

The loaded donor substrate 600 is first injected into the tub 230. In the tub 230, the residues remaining on the donor substrate 600 are washed with the solvent sprayed through the shower head 220 provided above the donor substrate 600. The washed residues are collected, together with the solvent, into the solvent collection tub 260 separately provided with the cleansing chamber 210 through a bottom of the tub 230.

Meanwhile, in the present invention, the donor substrate 600 is not abandoned as it is after the deposition of the organic layer is finished by the electric field applied from the electric field applying device 400, but again collected to the cleansing device 200 so as to cleanse the residues remaining in the cleansing device 200. Here, the residues are organic matters. Therefore, the organic matters are contained in the solvent collected in the solvent collection tub 260, and a separate organic matter separation tub (not shown) may be additionally provided to reuse the solvent and the organic matter. The organic matter separation tub is provided, so that it is possible to reduce the amount of the organic matter and solvent used.

The solvent separated from the organic matter separation tub is again collected to the solvent supply tub 250, and the separated organic matter is collected to an organic matter supply tub 340 of the organic matter coating device 300, which will be described later.

Additionally, in a case where the organic matter separation tub is provided, it is necessary to purge the collected solvent with a pure solvent in the solvent supply tub 250, and it is also necessary to purge the collected organic matter in the organic matter supply tub 340.

Subsequently, to completely remove the residues such as the solvent remaining on the donor substrate, the donor substrate 600 is transported to the blower 240 by a transportation mechanism such as a conveyer, and the remaining residues are completely removed using air in the blower 240.

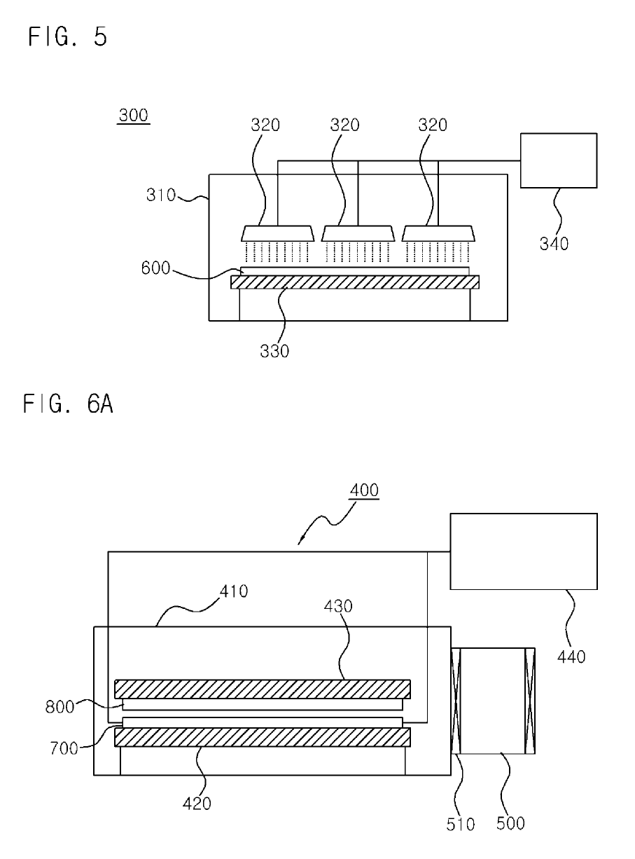

FIG. 5 is a view illustrating the organic matter coating device in the configuration of the deposition device according to the embodiment of the present invention.

As shown in FIG. 5, the organic matter coating device 300 includes a shower head 320 for spraying an organic matter in a coating chamber 310, a tub 330 for allowing the donor substrate 600 to be mounted thereon, and the organic matter supply tub 340.

The donor substrate 600 having the remaining residues completely removed therefrom is transported to the organic matter coating device 300 by the conveyer so as to be mounted on the tub 300 provided in the coating chamber 310. The organic matter coating device 300 is maintained under the nitrogen atmosphere, and the spray-type shower head 320 is provided at an upper portion of the organic matter coating device 300, so that the organic matter supplied from the organic matter supply tub 340 is sprayed onto the donor substrate 600.

The sprayed organic matter is stacked on the donor substrate 600 so as to form an organic layer. Here, the thickness of the organic layer formed on the donor substrate 600 is sufficient enough to cover the conductive layer formed on the donor substrate 600, and it is unnecessary to precisely control the thickness of the organic layer to be deposited. This is because the thickness of the organic layer to be deposited on an element substrate 700 can be adjusted by controlling the electric field applying condition of the electric field applying device 400 in a subsequent process. The organic matter coating device 300 may be further provided with an organic matter collection tub (not shown) connected through a pipe connected to the tub 330 so that the liquid-phase organic matter, which is not deposited but sprayed into the tub 330, is collected and again supplied to the organic matter supply tub 340.

Subsequently, the organic layer formed on the donor substrate 600 is dried, and the donor substrate 600 is then transported to the electric field applying device 400 by the conveyer.

Meanwhile, in the present invention, a drying device may be separately provided to dry the organic layer. Here, an ordinary drying device such as a hot plate may be used as the drying device.

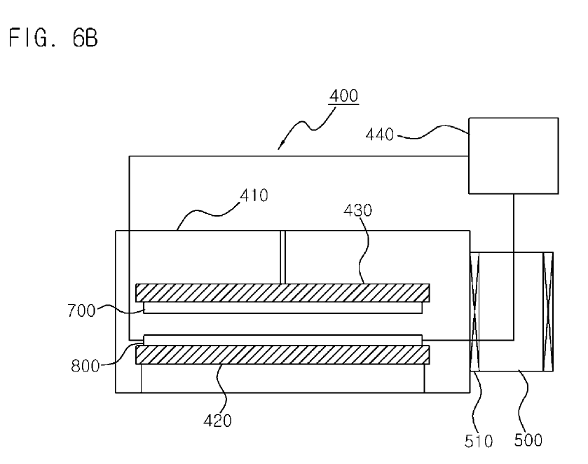

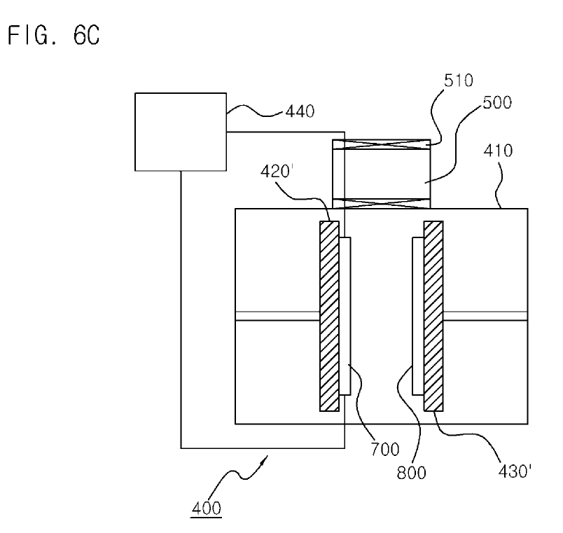

FIGS. 6A to 6C are views illustrating embodiments of the electric field applying device 400 in the configuration of the deposition device according to the present invention.

Referring to FIG. 6A, the electric field applying device 400 according to the embodiment of the present invention is provided with a loadlock chamber 500 having a gate 510 at a position at which the donor substrate 600 is loaded into an electric field applying chamber 410. The electric field applying device includes a stage 420 for mounting a substrate on a bottom thereof, a chuck 430 for transporting and fixing the substrate, and a power supply device 440 for applying an electric field. An electrode (not shown) for applying the electric field by coming in contact with a conductive layer formed on the donor substrate 600 is formed at one end of the power supply device 440.

Subsequently, the donor substrate 600 having an organic layer formed thereon is first loaded into the loadlock chamber 500 through the gate 510 by the conveyer. The donor substrate 600 loaded into the loadlock chamber 500 is transported to the electric field applying chamber 410 of the electric field applying device 400 by a transportation mechanism such as a robot. In this case, the electric field applying chamber 410 maintains a vacuum state.

The transported donor substrate 600 is mounted on the stage 420. In addition, the element substrate 700 for forming an organic layer thereon is transported to the electric field applying chamber 410 using the transportation mechanism and fixed to the chuck 430. The element substrate 700 is placed opposite to the donor substrate 600 mounted on the stage 430, and the two substrates are then joined together. Here, an electronic magnetic chuck (EMC) may be used as the chuck 430.

After the two substrates are joined together, the electric field applying electrode (not shown) comes in contact with the conductive layer formed on the donor substrate 600 and then receives an electric field from the power supply device 440. Since the electric field applying condition is determined by various factors such as resistance, length and thickness of the conductive layer, the electric field applying condition cannot be specified. However, the electric field application is performed in consideration of an ordinary processing condition.

Here, the applied current may be DC or AC, and the applied electric field may be 1 to 1,000 kw/cm². The time taken to apply the electric field once may be 1/1,000,000 to 100 seconds, preferably 1/1,000,000 to 10 seconds, and more preferably 1/1,000,000 to 1 second.

If the electric field applying electrode receives the electric field, Joule-heating is generated in the conductive layer formed on the donor substrate 600, and the generated Joule-heating is conducted to the organic layer formed above the donor substrate 600. The organic layer formed at a portion of the conductive layer is evaporated by the conducted Joule-heating and then transferred onto the element substrate 700 so that the organic layer is deposited on the element substrate 700. Subsequently, if the electric field applying process is finished, the donor substrate 600 is again transported to the cleansing device 200 via the loadlock chamber 500 by the conveyer, and the element substrate 700 is transported to another chamber for the purpose of a subsequent process.

Then, the cleansing process of the donor substrate 600 collected to the cleansing device 200 described above is performed, and the processes described above are repeated. Thus, the donor substrate according to the present invention can be continuously used by being circulated and reproduced, and the consumption of the organic matter can be reduced. Accordingly, it is possible to save fabrication cost.

Meanwhile, although FIG. 6A illustrates an example in which the donor substrate 600 and the element substrate 700 are respectively placed at lower and upper portions in the electric field applying device 400, the donor substrate 600 and the element substrate 700 may be respectively placed in the upper and lower portion in the electric field applying device 400, as described in FIG. 6B. As shown in FIG. 6C, both the donor substrate 600 and the element substrate 700 may be placed opposite to each other in the state in which the two substrates are vertically disposed.

According to the configuration described above, the donor substrate 600 may be reversed by the transportation mechanism (i.e., the robot) provided in the loadlock chamber 500 so as be placed at the upper portion or vertically disposed in the electric field applying device 400. The element substrate 700 may also be reversed or vertically disposed at the loading position by the transportation mechanism (the robot).

Here, embodiments in which the deposition device for forming the organic layer using the Joule-heating is applied to a device for fabricating an electroluminescent display device will be described in detail.

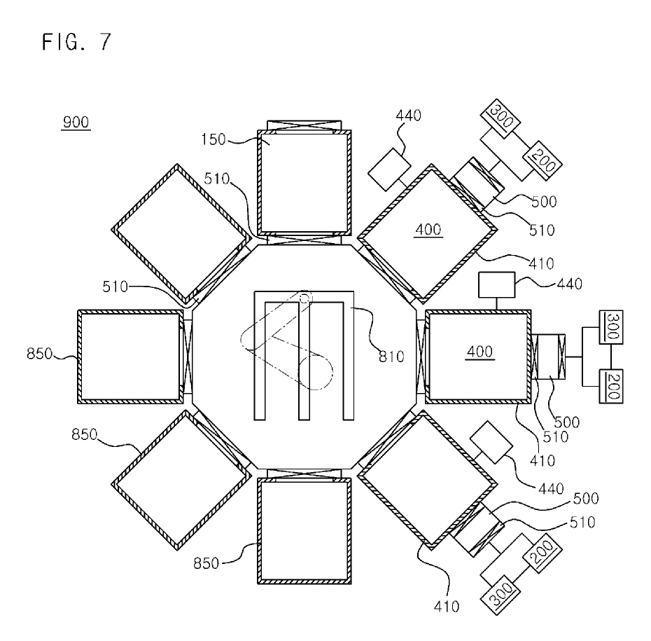

FIG. 7 is a plan view illustrating a device for fabricating an electroluminescent display device to which the deposition device of FIGS. 3 to 6C according to a first embodiment of the present invention. FIG. 7 illustrates an example in which deposition devices are provided in a cluster manner. Hereinafter, the deposition device applied to the embodiment of the present invention will be described with reference to FIGS. 3 to 6C.

Referring to FIG. 7, in the device 900 according to the first embodiment of the present invention, a conveying chamber 800 is placed at the center of the device 900, and a plurality of deposition chambers 850 and at least one deposition device 100 for forming the organic layer using the Joule-heating are arranged around the outer circumferential portion of the conveying chamber 800. The device 900 is further provided with the loadlock chamber 500 for receiving a substrate from the outside or carrying out the substrate from the conveying chamber 800.

A transportation mechanism 810 for transporting the substrate is provided in the conveying chamber 800, and a robot may be used as the transportation mechanism 810.

The deposition device 100 is configured to include the cleansing device 200, the organic matter coating device 300 and the electric field applying device 400. In the device 900 provided in the cluster manner, the electric field applying chamber 410 of the electric field applying device 400 in the configuration of the device 100 is combined with the conveying chamber 800 together with other deposition chambers 850.

Hereinafter, a detailed operating process of the device 900 according to the embodiment of the present invention will be described.

First, a donor substrate 600 on which an organic layer is formed as a layer is loaded into the cleansing device 200.

Referring to FIG. 4, the cleansing device 200 includes a cleansing chamber 210 maintained under a nitrogen atmosphere, a shower head 220 for cleansing the donor substrate 600, a tub 230 for accommodating a solvent for cleansing, sprayed from the shower head 220, and a blower 240 for removing residues remaining on the donor substrate 600. The cleansing device 200 further includes a solvent supply tub 250 for supplying the solvent for cleansing to the shower head 220, and a solvent collection tub 260 for collecting the solvent accommodated in the tub 230.

A conductive layer is formed on the donor substrate 600 so as to generate the Joule-heating in a subsequent electric field applying process. The conductive layer may be made of a metal or metal alloy. The metal or metal alloy may be, for example, Mo, Ti, Cr, MoW, etc. However, the present invention is not limited thereto.

Meanwhile, the conductive layer is formed to have a shape identical to that of an organic layer pattern to be stacked on the element substrate.

The loaded donor substrate 600 is first injected into the tub 230. In the tub 230, the residues remaining on the donor substrate 600 are washed with the solvent sprayed through the shower head 220 provided above the donor substrate 600. The washed residues are collected, together with the solvent, into the solvent collection tub 260 separately provided with the cleansing chamber 210 through a bottom of the tub 230.

Meanwhile, in the present invention, the donor substrate 600 is not abandoned as it is after the deposition of the organic layer is finished by the electric field applied from the electric field applying device 400, but again collected to the cleansing device 200 so as to cleanse the residues remaining in the cleansing device 200. Here, the residues are organic matters. Therefore, the organic matters are contained in the solvent collected in the solvent collection tub 260, and a separate organic matter separation tub (not shown) may be additionally provided to reuse the solvent and the organic matter. The organic matter separation tub is provided, so that it is possible to reduce the amount of the organic matter and solvent used.

The solvent separated from the organic matter separation tub is again collected to the solvent supply tub 250, and the separated organic matter is collected to an organic matter supply tub 340 of the organic matter coating device 300, which will be described later.

Additionally, in a case where the organic matter separation tub is provided, it is necessary to purge the collected solvent with a pure solvent in the solvent supply tub 250, and it is also necessary to purge the collected organic matter in the organic matter supply tub 340.

Subsequently, to completely remove the residues such as the solvent remaining on the donor substrate, the donor substrate 600 is transported to the blower 240 by a transportation mechanism such as a conveyer, and the remaining residues are completely removed using air in the blower 240.

The donor substrate 600 that has passed through the cleansing process in the cleansing device 200 is transported to the organic matter coating device 300 by the transportation means.

As shown in FIG. 5, the organic matter coating device 300 includes a shower head 320 for spraying an organic matter in a coating chamber 310, a tub 330 for allowing the donor substrate 600 to be mounted thereon, and the organic matter supply tub 340.

The transported donor substrate 600 is mounted on the tub 300 provided in the coating chamber 310. The organic matter coating device 300 is maintained under the nitrogen atmosphere, and the spray-type shower head 320 is provided at an upper portion of the organic matter coating device 300, so that the organic matter supplied from the organic matter supply tub 340 is sprayed onto the donor substrate 600.

The sprayed organic matter is stacked on the donor substrate 600 so as to form an organic layer. Here, the thickness of the organic layer formed on the donor substrate 600 is sufficient enough to cover the conductive layer formed on the donor substrate 600, and it is unnecessary to precisely control the thickness of the organic layer to be deposited. This is because the thickness of the organic layer to be deposited on an element substrate 700 can be adjusted by controlling the electric field applying condition of the electric field applying device 400 in a subsequent process. Subsequently, the organic layer formed on the donor substrate 600 is dried, and the donor substrate 600 is then transported to the electric field applying device 400 by the conveyer.

In this embodiment, a drying device may be separately provided to dry the organic layer. Here, an ordinary drying device such as a hot plate may be used as the drying device.

As shown in FIG. 6A, the electric field applying device 400 is provided with a loadlock chamber 500 having a gate 510 at a position at which the donor substrate 600 is loaded into an electric field applying chamber 410. The electric field applying device includes a stage 420 for mounting a substrate on a bottom thereof, a chuck 430 for transporting and fixing the substrate, and a power supply device 440 for applying an electric field. An electrode (not shown) for applying the electric field by coming in contact with a conductive layer formed on the donor substrate 600 is formed at one end of the power supply device 440.

The donor substrate 600 having an organic layer formed thereon is first loaded into the loadlock chamber 500 through the gate 510 by the conveyer. The donor substrate 600 loaded into the loadlock chamber 500 is transported to the electric field applying chamber 410 of the electric field applying device 400 by a transportation mechanism such as a robot. In this case, the electric field applying chamber 410 maintains a vacuum state.

Subsequently, the donor substrate 600 is mounted on the stage 420.

Meanwhile, as shown in FIGS. 6A and 7, the element substrate 700 that includes a TFT and has a first electrode formed therein is loaded into the conveying chamber 800 through the loadlock chamber 500 having the gate 510 by the transportation mechanism. The element substrate 700 loaded into the conveying chamber 800 is loaded into the electric field applying chamber 410 of the electric field applying device 400 in each of the deposition devices 100 arranged around the outer circumferential portion of the conveying chamber 800 by a conveying mechanism.

The element substrate 700 loaded into the electric field applying chamber 410 is fixed to the chuck 430. The element substrate 700 is placed opposite to the donor substrate 600 mounted on the stage 430, and the two substrates are then joined together. Here, an EMC may be used as the chuck 430.

After the two substrates are joined together, the electric field applying electrode (not shown) comes in contact with the conductive layer formed on the donor substrate 600 and then receives an electric field from the power supply device 440. Since the electric field applying condition is determined by various factors such as resistance, length and thickness of the conductive layer, the electric field applying condition cannot be specified. However, the electric field application is performed in consideration of an ordinary processing condition.

Here, the applied current may be DC or AC, and the applied electric field may be 1 to 1,000 kw/cm². The time taken to apply the electric field once may be 1/1,000,000 to 100 seconds, preferably 1/1,000,000 to 10 seconds, and more preferably 1/1,000,000 to 1 second.

If the electric field applying electrode receives the electric field, Joule-heating is generated in the conductive layer formed on the donor substrate 600, and the generated

Joule-heating is conducted to the organic layer formed above the donor substrate 600. The organic layer formed at a portion of the conductive layer is evaporated by the conducted Joule-heating and then transferred onto the element substrate 700 so that the organic layer is deposited on the element substrate 700. Subsequently, if the electric field applying process is finished, the donor substrate 600 is again transported to the cleansing device 200 via the loadlock chamber 500 by the conveyer, and the element substrate 700 is transported from the conveying chamber 800 to another deposition device 100 via the loadlock chamber 500 by a transportation mechanism 910.

In addition, the processes described above are repeated, so that a plurality of organic layers can be deposited on the element substrate 700.

As such, a plurality of deposition devices 100 are provided by changing only an organic matter while equally maintaining the configuration of the deposition device 100, and the process describe above is repeated, so that a plurality of organic layers can be simply and easily deposited on the element substrate 700.

The organic layer essentially includes an organic light emitting layer, and may selectively use at least one of a pixel defining layer, a hole injection layer, a hole transport layer, a hole blocking layer, an electron blocking layer, an electron transport layer and an electron injection layer, as functional layers of the electroluminescent display device. The organic light emitting layer may include not only a single light emitting layer but also R, G and B light emitting layers.

In this embodiment, the cleansing and organic matter coating processes described above are performed, and the processes described above are repeated. Thus, the donor substrate according to the present invention can be continuously used by being circulated and reproduced, and the consumption of the organic matter can be reduced. Accordingly, it is possible to save fabrication cost.

Meanwhile, although FIG. 6A illustrates an example in which the donor substrate 600 and the element substrate 700 are respectively placed at lower and upper portions in the electric field applying device 400, the donor substrate 600 and the element substrate 700 may be respectively placed in the upper and lower portion in the electric field applying device 400, as described in FIG. 6B. As shown in FIG. 6C, both the donor substrate 600 and the element substrate 700 may be placed opposite to each other in the state in which the two substrates are vertically disposed.

According to the configuration described above, the donor substrate 600 may be reversed by the transportation mechanism (i.e., the robot) provided in the loadlock chamber 500 so as be placed at the upper portion or vertically disposed in the electric field applying device 400. The element substrate 700 may also be reversed or vertically disposed at the loading position by the transportation mechanism (the robot).

After the deposition of the organic layer on the element substrate 700 of the electroluminescent display device is finished by repeating the deposition process, the element substrate 700 is transported from the conveying chamber 800 to one of the deposition chambers 850 by the transportation mechanism 810.

In the deposition chamber 850, an upper electrode is formed on the element substrate 700. An anode or cathode electrode may be formed as the upper electrode, and the upper electrode may be formed as a transparent or reflective electrode using a metal layer, conductive oxide layer, etc.

The deposition chamber for forming the upper electrode may use an ordinary device including a sputtering device, a deposition device, etc. Additionally, after the upper electrode is formed, a protection layer may be deposited on the upper electrode in each of the other deposition chambers 850.

Subsequently, after the upper electrode is formed and the element substrate is then conveyed to the conveying chamber 800, the element substrate is transported from the conveying chamber 800 to an encapsulation chamber so that an encapsulating process is finished. Accordingly, the fabrication of the electroluminescent display device is completed.

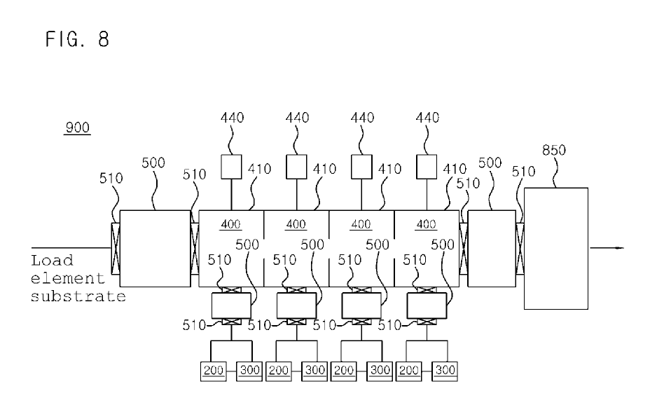

FIG. 8 is a plan view illustrating a device for fabricating an electroluminescent display device to which the deposition device 100 of FIGS. 3 to 6C according to a second embodiment of the present invention. The second embodiment is an embodiment configured using an in-line apparatus.

Referring to FIGS. 3 and 8, the device according to the second embodiment of the present invention includes deposition devices 100 for forming an organic layer using Joule-heating, loadlock chambers 500 each having a gate 510, which loads an element substrate 700 into the deposition device 100 and carries out the element substrate 700 from the deposition device 100, and at least one deposition chamber connected to the deposition device 100 and the loadlock chamber 500 for carrying out the element substrate 700. The deposition device 100 includes a cleansing device 200 for cleansing a donor substrate, an organic matter coating device 200 for coating an organic matter on the donor substrate, a loadlock chamber 500 for loading the donor substrate having the organic matter coated thereon into an electric field applying device 400, the electric field applying device 400 that allows the organic matter to be transferred onto an element substrate, and the loadlock chamber 500 for loading or carrying out the donor substrate into/from the electric field applying device 400. Here, the organic matter is heated by the Joule-heating generated by applying an electric field to the donor substrate having the organic matter formed thereon.

If the loadlock chamber 500 for loading the element substrate 700 is connected to one end of the deposition device 100, the loadlock chamber for carrying out the element substrate 700 is connected to the other end of the deposition device 100. The loadlock chamber 500 for loading/carrying out the element substrate 700 is different from the loadlock chamber into which the donor substrate 600 having the organic layer formed thereon, transported from the organic matter coating device 300, is loaded.

In the deposition device 100, the electric field applying chamber 410 of the electric field applying device 400 is coupled to the loadlock chamber 500 for loading/carrying out the element substrate 700.

At least one deposition devices may be additionally provided in series between the deposition device 100 and the loadlock chamber 500 for carrying out the element substrate 700. In this case, the electric field applying chambers 410 of the electric field applying devices 400 in the deposition devices 100 are connected in series to one another.

When the electric field applying chambers 410 are connected in series to one another, the electric field applying chambers 410 are not formed in a separated structure but formed in a connected structure, so that the element substrate 700 can be transported to the electric field applying chambers 410 connected to one another by a consecutive transportation means such as a conveyer.

Hereinafter, a detailed operating process of the device 800 according to the second embodiment of the present invention will be described, and detailed descriptions of configurations and operations identical to those of the first embodiment will be omitted to avoid redundancy.

First, the configurations and operations of the cleansing device 200 for cleansing the donor substrate 600 and the organic matter coating device 300 for coating the organic matter on the donor substrate 600 are identical to those of the first embodiment, and therefore, their detailed descriptions will be omitted to avoid redundancy.

Subsequently, as shown in FIG. 6A, the donor substrate 600 having the organic layer formed thereon is transported from the organic matter coating device 300 by the transportation means and then loaded into the electric field applying chamber 410 of the electric field applying device 400 via the loadlock chamber 500 having the gate 510. The configuration of the electric field applying device 400 is also identical to that of the first embodiment, and therefore, its detailed description will be omitted. In this case, the electric field applying chamber 410 maintains a vacuum state.

Subsequently, the donor substrate 600 is mounted on the stage 420.

Meanwhile, as shown in FIGS. 6A and 8, the element substrate 700 that includes a TFT and has a first electrode formed therein is loaded into the electric field applying chamber 410 of the electric field applying device 400 through the loadlock chamber 500 having the gate 510 by the transportation mechanism. The element substrate 700 loaded into the conveying chamber 800 is loaded into the electric field applying chamber 410 of the electric field applying device 400 in each of the deposition devices 100 arranged around the outer circumferential portion of the conveying chamber 800 by a conveying mechanism.

The element substrate 700 loaded into the electric field applying chamber 410 is fixed to the chuck 430. The element substrate 700 is placed opposite to the donor substrate 600 mounted on the stage 430, and the two substrates are then joined together.

After the two substrates are joined together, the electric field applying electrode (not shown) comes in contact with the conductive layer formed on the donor substrate 600 and then receives an electric field from the power supply device 440. Since the electric field applying condition is determined by various factors such as resistance, length and thickness of the conductive layer, the electric field applying condition cannot be specified. However, the electric field application is performed in consideration of an ordinary processing condition.

Here, the applied current may be DC or AC, and the applied electric field may be 1 to 1,000 kw/cm². The time taken to apply the electric field once may be 1/1,000,000 to 100 seconds, preferably 1/1,000,000 to 10 seconds, and more preferably 1/1,000,000 to 1 second.

If the electric field applying electrode receives the electric field, Joule-heating is generated in the conductive layer formed on the donor substrate 600, and the generated Joule-heating is conducted to the organic layer formed above the donor substrate 600. The organic layer formed at a portion of the conductive layer is evaporated by the conducted Joule-heating and then transferred onto the element substrate 700 so that the organic layer is deposited on the element substrate 700.

Subsequently, if the electric field applying process is finished, the donor substrate 600 is again transported to the cleansing device 200 via the loadlock chamber 500 by the conveyer, and the element substrate 700 is transported to the conveying chamber connected to the loadlock chamber 500 for carrying out the element substrate 700 via the loadlock chamber 500 for carrying out the element substrate 700.

Meanwhile, in a case where at least one deposition device is additionally provided in series between the deposition device 100 and the loadlock chamber 500 for carrying out the element substrate 700, the electric field applying chambers 410 of the electric field applying devices 400 in the deposition devices 100 are connected in series to one another, as described above. In this case, the electric field applying chambers 410 are not formed in a separated structure but formed in a connected structure, so that the element substrate 700 can be transported to the electric field applying chambers 410 connected to one another by a consecutive transportation means such as a conveyer.

Therefore, in a case where the at least one deposition device is additionally provided, the element substrate 700 that has passed through the electric field applying process described above is transported to a second electric field applying chamber 410 connected in series to a first electric field applying chamber 410 by a consecutive transportation means such as a conveyer.

The cleansing and organic matter coating processes of the element substrate 700 transported to the second electric field applying chamber 410 are finished by a second deposition device so as to be combined with the donor substrate 600 loaded into the second electric field applying chamber 410. Then, a second organic layer is deposited by again performing the electric field applying process.

The processes described above are repeated, so that a plurality of organic layers can be consecutively deposited on the element substrate 700.

Although it has been illustrated in that four deposition devices 100 are configured, the present invention is not limited thereto, and the number of the deposition devices 100 may be increased/decreased when necessary.

Meanwhile, the organic layer essentially includes an organic light emitting layer, and may selectively use at least one of a pixel defining layer, a hole injection layer, a hole transport layer, a hole blocking layer, an electron blocking layer, an electron transport layer and an electron injection layer, as functional layers of the electroluminescent display device. The organic light emitting layer may include not only a single light emitting layer but also R, G and B light emitting layers.

If the process of depositing the organic layer on the element substrate 700 through the processes described above, the element substrate 700 is transported to one of the deposition chambers 850 through the loadlock chamber 500 for carrying out the element substrate 700. Here, at least one deposition chamber 850 may be provided.

In the deposition chamber 850, an upper electrode is formed on the element substrate 700. An anode or cathode electrode may be formed as the upper electrode, and the upper electrode may be formed as a transparent or reflective electrode using a metal layer, conductive oxide layer, etc.

The deposition chamber for forming the upper electrode may use an ordinary device including a sputtering device, a deposition device, etc. Additionally, after the upper electrode is formed, a protection layer may be deposited on the upper electrode in each of the other deposition chambers 850.

Subsequently, after the upper electrode is formed and the element substrate is then conveyed to the conveying chamber 800, the element substrate is transported from the conveying chamber 800 to an encapsulation chamber so that an encapsulating process is finished. Accordingly, the fabrication of the electroluminescent display device is completed.

In the related art, most other layers in the electroluminescent display device are formed through the deposition device, and particularly, an organic light emitting layer is formed through patterning. Therefore, the organic light emitting layer is generally formed using a deposition device using a mask. However, since an organic layer deposition chamber and a reversing chamber are added to the related art device, a high-priced deposition chamber is used. Accordingly, there occurs a disadvantage in that when an organic layer is formed through a deposition process, fabrication cost is increased, and fabrication time is lengthened. On the other hand, in a case where the deposition device is configured and applied to the device for fabricating the electroluminescent display device in the present invention, such a disadvantage can be overcome.

Further, since the process of depositing the organic layer through the electric field applying process is performed for a very short time as compared with the related art deposition process, the entire processing time can be reduced, thereby saving processing cost.

Further, since the configuration of the deposition device for forming the organic layer using the Joule-heating in the present invention is much simpler than that of the related art deposition device, it is possible to save device fabrication cost.

Further, since the device of the present invention is easily configured using an in-line apparatus, it is possible to reduce processing time and to save processing cost and device fabrication cost.

While the present invention has been illustrated and described in connection with the accompanying drawings and the preferred embodiments, the present invention is not limited thereto and is defined by the appended claims. Therefore, it will be understood by those skilled in the art that various modifications and changes can be made thereto without departing from the spirit and scope of the invention defined by the appended claims.

What is claimed is:

1. A deposition device for forming an organic layer using Joule heating, comprising:
a cleansing device configured to cleanse a donor substrate;
an organic matter coating device configured to coat an organic matter on the donor substrate;
an electric field applying device configured to allow the organic matter to be transferred onto an element substrate, wherein the organic matter is heated by the Joule-heating generated by applying an electric field to the donor substrate having the organic matter formed thereon; and
a loadlock chamber configured to load or carry out the donor substrate into/from the electric field applying device.

2. The deposition device of claim 1, wherein the cleansing device comprises:
a solvent supply tub configured to supply a solvent;
a shower head configured to spray the solvent supplied from the solvent supply tub onto the donor substrate;
a tub configured to accommodate the solvent sprayed from the shower head and the organic matter dissolved in the solvent;
a blower configured to blow and remove remaining solvent not removed in the tub and the organic matter dissolved in the remaining solvent; and
a solvent collection tub configured to collect the solvent and the organic matter, accommodated in the tub.

3. The deposition device of claim 2, further comprising an organic matter separation tub configured to be connected to the solvent collection tub,
wherein the organic matter separation tub separates the solvent and the organic matter, collected in the solvent collection tub, and the separated organic matter is again supplied to the organic matter coating device.

4. The deposition device of claim 1, wherein the organic matter coating device comprises:
a shower head configured to spray an organic matter;
a stage configured to mount the donor substrate; and
an organic matter supply tub configured to be connected to the shower head so as to supply the organic matter.

5. The deposition device of claim 1, further comprising a drying device.

6. The deposition device of claim 1, wherein the electric field applying device comprises:
a power supply device;
an electric field applying electrode configured to be electrically connected to the power supply device;
a stage configured to mount a substrate; and
a chuck configured to be placed opposite to the stage.

7. A device for fabricating an electroluminescent display device, comprising:
a conveying chamber configured to have a conveying mechanism for conveying a substrate;
at least one deposition chamber configured to be placed at an outside of the conveying chamber;
at least one deposition device for forming an organic layer using Joule-heating; and
a loadlock chamber configured to load the substrate into the conveying chamber or carry out the substrate from the conveying chamber,
wherein the deposition device comprises:
a cleansing device configured to cleanse a donor substrate;
an organic matter coating device configured to coat an organic matter on the donor substrate;
an electric field applying device configured to allow the organic matter to be transferred onto an element substrate, wherein the organic matter is heated by the Joule-heating generated by applying an electric field to the donor substrate having the organic matter formed thereon; and
a loadlock chamber configured to load or carry out the donor substrate into/from the electric field applying device.

8. The device of claim 7, wherein the cleansing device comprises:
a solvent supply tub configured to supply a solvent;
a shower head configured to spray the solvent supplied from the solvent supply tub onto the donor substrate;
a tub configured to accommodate the solvent sprayed from the shower head and the organic matter dissolved in the solvent;
a blower configured to blow and remove remaining solvent not removed in the tub and the organic matter dissolved in the remaining solvent; and
a solvent collection tub configured to collect the solvent and the organic matter, accommodated in the tub.

9. The device of claim 8, wherein the deposition device further comprises an organic matter separation tub configured to be connected to the solvent collection tub, the organic matter separation tub separates the solvent and the organic matter, collected in the solvent collection tub, and the separated organic matter is again supplied to the organic matter coating device.

10. The device of claim 7, wherein the organic matter coating device comprises:
a shower head configured to spray an organic matter;
a stage configured to mount the donor substrate; and
an organic matter supply tub configured to be connected to the shower head so as to supply the organic matter.

11. The device of claim 7, wherein the deposition device further comprises a drying device.

12. The device of claim 7, wherein the electric field applying device comprises:
a power supply device;
an electric field applying electrode configured to be electrically connected to the power supply device;
a stage configured to mount a substrate; and
a chuck configured to be placed opposite to the stage.

13. The device of claim 7, wherein the at least one deposition device is a deposition device for forming at least one of a hole injection layer, a hole transport layer, a hole blocking layer, a light emitting layer, an electron blocking layer, an electron transport layer and an electron injection layer.

14. A device for fabricating an electroluminescent display device, comprising:
a loadlock chamber configured to load an element substrate;
a deposition device for forming an organic layer using Joule-heating, configured to have one end connected to the loadlock chamber;
a loadlock chamber for carrying out the element substrate, configured to carry out the element substrate, and be connected to the other end of the deposition device; and
at least one deposition chamber configured to be connected to the loadlock chamber,
wherein the deposition device comprises:
a cleansing device configured to cleanse a donor substrate;
an organic matter coating device configured to coat an organic matter on the donor substrate;
an electric field applying device configured to allow the organic matter to be transferred onto an element substrate, wherein the organic matter is heated by the Joule-heating generated by applying an electric field to the donor substrate having the organic matter formed thereon; and
a loadlock chamber configured to load or carry out the donor substrate into/from the electric field applying device.

15. The device of claim 14, wherein the cleansing device comprises:
a solvent supply tub configured to supply a solvent;
a shower head configured to spray the solvent supplied from the solvent supply tub onto the donor substrate;
a tub configured to accommodate the solvent sprayed from the shower head and the organic matter dissolved in the solvent;
a blower configured to blow and remove remaining solvent not removed in the tub and the organic matter dissolved in the remaining solvent; and
a solvent collection tub configured to collect the solvent and the organic matter, accommodated in the tub.

16. The device of claim 15, wherein the deposition device further comprises an organic matter separation tub configured to be connected to the solvent collection tub, the organic matter separation tub separates the solvent and the organic matter, collected in the solvent collection tub, and the separated organic matter is again supplied to the organic matter coating device.

17. The device of claim 14, wherein the organic matter coating device comprises:
a shower head configured to spray an organic matter;
a stage configured to mount the donor substrate; and
an organic matter supply tub configured to be connected to the shower head so as to supply the organic matter.

18. The device of claim 14, wherein the deposition device further comprises a drying device.

19. The device of claim 14, wherein the electric field applying device comprises:
a power supply device;
an electric field applying electrode configured to be electrically connected to the power supply device;
a stage configured to mount a substrate; and
a chuck configured to be placed opposite to the stage.

20. The device of claim 14, wherein the at least one deposition device is a deposition device for forming at least one of a hole injection layer, a hole transport layer, a hole blocking layer, a light emitting layer, an electron blocking layer, an electron transport layer and an electron injection layer.
